(19) United States
(12) Patent Application Publication
(10) Pub. No.: US 2023/0395549 A1
(43) Pub. Date: Dec. 7, 2023

(54) INTEGRATED CIRCUIT DEVICES WITH ELECTRICAL CONTACTS ON MULTIPLE SURFACES

(71) Applicant: Hewlett-Packard Development Company, L.P., Spring, TX (US)

(72) Inventors: DAVID WAYNE GEORGE, PALO ALTO, CA (US); KRISTOPHER J. ERICKSON, PALO ALTO, CA (US); JARRID WITTKOPF, PALO ALTO, CA (US)

(21) Appl. No.: 18/032,526

(22) PCT Filed: Oct. 19, 2020
(86) PCT No.: PCT/US2020/056289

§ 371 Date: Apr. 18, 2023

(51) Int. Cl. H01L 23/00; H01L 23/31; H01L 23/495

(52) U.S. Cl. CPC H01L 24/14; H01L 24/13; H01L 23/3157; H01L 23/49572; H01L 24/11; H01L 24/81; H01L 24/16; H01L 2224/13021; H01L 2224/14181; H01L 2224/13025; H01L 2224/11831; H01L 2224/1184; H01L 2224/81193; H01L 2224/11318; H01L 2224/16245; H01L 2224/16227; H01L 2224/13111; H01L 2224/13139; H01L 2224/13147

(57) ABSTRACT

In one example in accordance with the present disclosure, an integrated circuit device is described. The integrated circuit device includes an integrated circuit die that includes a first surface and a second surface. A first electrical contact is disposed on the first surface of the integrated circuit die and a second electrical contact is disposed on the second surface of the integrated circuit die.

### BACKGROUND

An integrated circuit is a set of electronic components such as resistors, transistors, capacitors, and diodes that interoperate together to execute certain computing operations. For example, integrated circuits can perform calculations and store data.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a block diagram of an integrated circuit device with electrical contacts on multiple surfaces, according to an example of the principles described herein.

FIG. 2 is a diagram of an integrated circuit device with electrical contacts on multiple surfaces, according to an example of the principles described herein.

FIG. 3 is a diagram of an integrated circuit device with electrical contacts on multiple surfaces, according to another example of the principles described herein.

FIG. 4 is a diagram of an integrated circuit with electrical contacts on multiple surfaces disposed within a three-dimensional (3D) printed object, according to an example of the principles described herein.

FIG. 5 is a diagram of an integrated circuit device with electrical contacts on multiple surfaces, according to another example of the principles described herein.

FIG. 6 is a flow chart of a method for forming integrated circuit devices with electrical contacts on multiple surfaces, according to an example of the principles described herein.

FIG. 7 is a flow chart of a method for forming integrated circuit devices with electrical contacts on multiple surfaces, according to another example of the principles described herein.

FIG. 8 is a flow chart of a method for forming integrated circuit devices with electrical contacts on multiple surfaces, according to another example of the principles described herein.

FIGS. 9A-E depict the formation of electrical contacts on multiple surfaces of an integrated circuit device, according to an example of the principles described herein.

FIG. 10 is a diagram of an integrated circuit device with electrical contacts on multiple surfaces, according to another example of the principles described herein.

FIG. 11 is a diagram of an integrated circuit device with electrical contacts on multiple surfaces, according to another example of the principles described herein.

FIG. 12 is a diagram of an integrated circuit device with electrical contacts on multiple surfaces, according to another example of the principles described herein.

FIGS. 13A and 13B are diagrams of an integrated circuit device with electrical contacts on multiple surfaces, according to another example of the principles described herein.

FIG. 14 is a diagram of an integrated circuit device with electrical contacts on multiple surfaces, according to another example of the principles described herein.

FIG. 15 is a diagram of an integrated circuit device with electrical contacts on multiple surfaces, according to another example of the principles described herein.

FIG. 16 is a flow chart of a method for forming integrated circuit devices with electrical contacts on multiple surfaces in a 3D printed object, according to another example of the principles described herein.

FIG. 17 is a flow chart of a method for forming integrated circuit devices with electrical contacts on multiple surfaces in a 3D printed object, according to another example of the principles described herein.

FIGS. 18A and 18B depict placement of an integrated circuit device with electrical contacts on multiple surfaces into a 3D printed object, according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

An integrated circuit device includes a silicon substrate on which electronic components such as transistors, resistors, capacitors, and diodes are formed. Integrated circuits are a fundamental component of electronic, electric, and computing devices. An integrated circuit device may include a semiconductor device built in or onto silicon, or another suitable substrate, and the number of electronic circuits disposed thereon. The integrated circuit device may also include electrical traces that couple these electronic components together. That is, an integrated circuit device includes the integrated circuit substrate and disposed components and connections, and may include a protective coating such as a molded epoxy resin compound that is formed around the integrated circuit die. Such integrated circuit devices may be referred to as chips or processors. While semiconductor usage has without a doubt advanced modern society, developments to their operation and structure may even further increase their utility and use throughout existing markets and in new markets.

For example, integrated circuit devices may be formed for use on printed circuit boards and assemblies (PCB, PCA), flex circuits, and other circuit assemblies that involve attachment of the integrated circuit device onto a two-dimensional (2D) surface. Certain features of these integrated circuit devices and the methods for making the same are therefore selected for use in a 2D environment. That is, these integrated circuit devices may not be structured to be utilized in a 3-dimensional environment and more specifically not for use in 3D printed objects. Below are some examples of the characteristics of a 2D environment that drive integrated circuit device production. Specifically, leads are connected to a 2D surface and lead metal and surface coatings are formed to facilitate solder wetting and solderability. The surface area of the integrated circuit devices may be selected to enable denser placement of components on a surface. Other examples include lead/ball density being selected for device density and components being placed at as fine a pitch as PCB and solder capability allows. These integrated circuit devices are also structured to withstand solder reflow temperature profiles (i.e., over 220 degrees Celsius (C) for ˜30 s), facilitate in-circuit tests (ICTs) with an array of probes, and include thermal planes and heat sinks for heat dissipation.

By comparison, the integrated circuit devices of the present specification are selected to align with additive manufacturing processes and to be inserted into 3D printed electronics. For example, integrated circuit devices of the present specification may include electrical contacts on multiple, and in some cases all, surfaces as all surfaces may be accessible via printed conductive traces in the 3D printed object. Moreover, the electrical contacts may be formed for direct contact to conductive agents, rather than soldering. The pad size/pitch may be determined by voxel resolution and agent spreading. The materials may be selected to withstand the polymer fusing temperature profile, which may be cooler than a solder profile. As another example, the integrated circuit device may be as thick as one layer of printed build material where a planar density is not a manufacturing constraint. As the integrated circuit device is embedded in a 3D body, the connectivity of the integrated circuit device is tested during or shortly after processing/placement.

Accordingly, the present specification describes processes to allow the creation and production of integrated circuit devices that are tailored for use in 3D printed electronics and that can withstand the additive manufacturing conditions and environment.

Specifically, other integrated circuits may have power and signal inputs and outputs on a single plane. The present specification describes an integrated circuit device with electrical contacts on multiple surfaces. The present specification also describes methods for forming such an integrated circuit device and placing it into a 3D printed object. It should be noted that the present specification describes electronic contacts on either side of an integrated circuit die itself as well as on multiple sides of a packaged integrated circuit device.

Specifically, the present specification describes an integrated circuit device. The integrated circuit device includes an integrated circuit die having a first surface and a second surface. A first electrical contact is disposed on the first surface of the integrated circuit die and a second electrical contact is disposed on the second surface of the integrated circuit die.

The present specification also describes a method. According to the method, an integrated circuit die is provided that includes a first surface and a second surface, which surfaces are opposite one another. A first electrical contact is formed on the first surface of the integrated circuit die and a second electrical contact is formed on the second surface of the integrated circuit die.

The present specification also describes a method for forming an integrated circuit device. According to the method, an integrated circuit die having electrical contacts on a surface is provided. The integrated circuit die is flip chip mounted to a lead frame such that the electrical contacts align with leads on the lead frame. The integrated circuit die and the lead frame are encapsulated in an encapsulant. A lead support structure is removed from the leads of the lead frame and the leads are folded around the encapsulant to form an integrated circuit device.

Such devices and methods 1) allow contact at, and efficient wiring to, multiple surfaces of the integrated circuit device rather than simply one planar surface; 2) enable manufacturing of integrated circuit devices to deliver flexible geometry; 3) enable the construction of devices for single-layer thickness; and 4) are tailored for additive manufacturing operations, including reducing movement after placement and ensuring contact quality in a non-soldered contact. However, it is contemplated that the systems and methods disclosed herein may address other matters and deficiencies in a number of technical areas.

As used in the present specification and in the appended claims, the term “integrated circuit die” refers to the combination of 1) a substrate, such as silicon and 2) the electrical components disposed on or embedded within the substrate.

Moreover, as used in the present specification and in the appended claims, the term “integrated circuit device” refers to the integrated circuit die and electrical contacts (i.e., bumps or leads) formed thereon and may include an encapsulant. In some examples, the integrated circuit device includes electrical contacts formed on the die of the integrated circuit device. In other examples, the integrated circuit device includes electrical contacts formed on the encapsulant of the integrated circuit device.

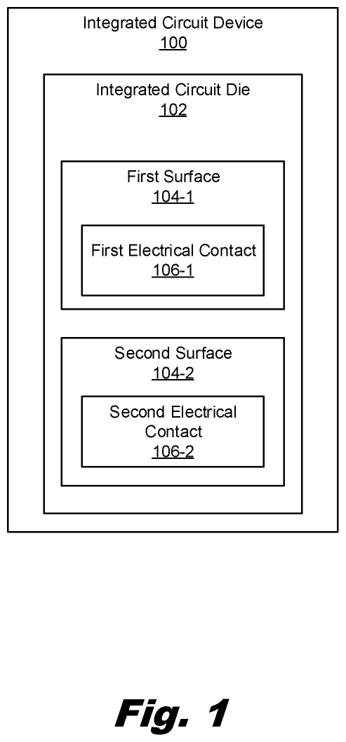

Turning now to the figures, FIG. 1 is a block diagram of an integrated circuit device (100) with electrical contacts (106) on multiple surfaces (104), according to an example of the principles described herein. In the example depicted in FIGS. 1-7, the surface (104) on which the electrical contacts are formed are the surfaces of the integrated circuit die (102) itself. That is, the integrated circuit device (100) includes an integrated circuit die (102) which has a first surface (104-1) and a second surface (104-2). In some examples, the second surface (104-2) may be opposite the first surface (104-1). That is, the first surface (104-1) may be referred to as a “top” surface and the second surface (104-2) may be referred to as a “bottom” surface. The integrated circuit die (102) may include a silicon wafer substrate with electrical components formed on the surfaces (104) or embedded within the body of the silicon wafer substrate.

A first electrical contact (106-1) may be disposed on the first surface (104-1) while a second electrical contact (106-2) is disposed on the second surface (104-2). That is, where other integrated circuit devices have electrical contacts on a single planar surface. By comparison, the integrated circuit device (100) of the present specification includes electrical contacts (106) on different, and in some examples opposite, surfaces (104). Doing so allows for the integrated circuit device (100) to be used in a wider variety of applications. That is, rather than being limited to forming electrical connections on a first surface (104-1) where space may be limited, electrical connections may also be formed on the second surface (104-2) thus providing a potentially greater connection density. Accordingly, in applications where both surfaces (104) are accessible for electrical connection, such as in a 3D printed object, the integrated circuit device (100) of the present specification provides greater flexibility and customization for generating an electronic component.

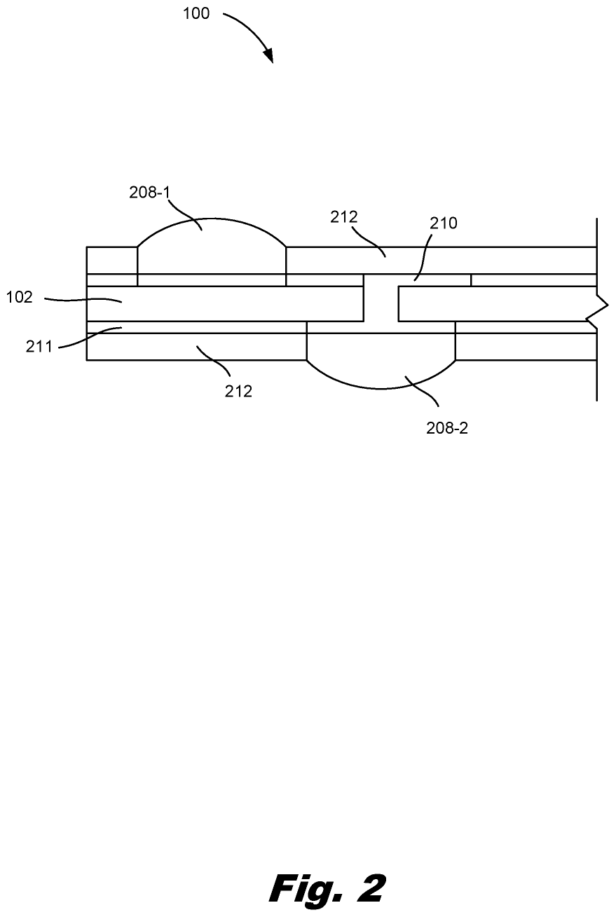

The electrical contacts (106) may be formed in a variety of ways. For example, as depicted in at least FIGS. 2, 3, 5, and 7, electrically conductive bumps may be formed on opposite sides of the integrated circuit die (102). Accordingly, the integrated circuit device (100) as described herein provides electrical contacts (106) for electrical traces, and provides those electrical contacts (106) not just on a single surface (104) but on multiple different surfaces. The figures below provide examples of additional features of the integrated circuit device (100) that facilitate their insertion into a 3D printed object.

FIG. 2 is a diagram of an integrated circuit device (100) with electrical contacts (FIG. 1, 106) on multiple surfaces (FIG. 1, 104), according to an example of the principles described herein. As clearly depicted in FIG. 2, electrical contacts (FIG. 1, 106) may be formed on opposite sides of the integrated circuit device (100) such that the integrated circuit device (100) may make contact with electrical traces on either of these surfaces (FIG. 1, 104). This may facilitate the integrated circuit device (100) usage within a 3D printed electronic. For example, in a PCB or PCA application, electrical contacts (FIG. 1, 106) are on a single surface (FIG. 1, 104), rather than multiple surfaces (FIG. 1, 104). However, with electrical contacts (FIG. 1, 106) on both surfaces (FIG. 1, 104), electrical connection may be made with either side of the integrated circuit device (100) thus providing more connection points and greater flexibility in the positioning of those electrical contacts (FIG. 1, 106).

In the example depicted in FIG. 2, the electrical contacts (FIG. 1, 106) are bumps (208-1, 208-2) of an electrically conductive material. The bumps (208) sit on bond pads which receive and transmit electrical signals to and from the integrated circuit die (102) and the associated circuit components thereon. Note that while FIG. 2 depicts an example integrated circuit device (100) with one metal wiring layer disposed on the integrated circuit die (102) and connected by a through silicon via (210) to the opposite side, integrated circuit devices (100) may include multiple layers of wiring between the die (102) and the bumps (208).

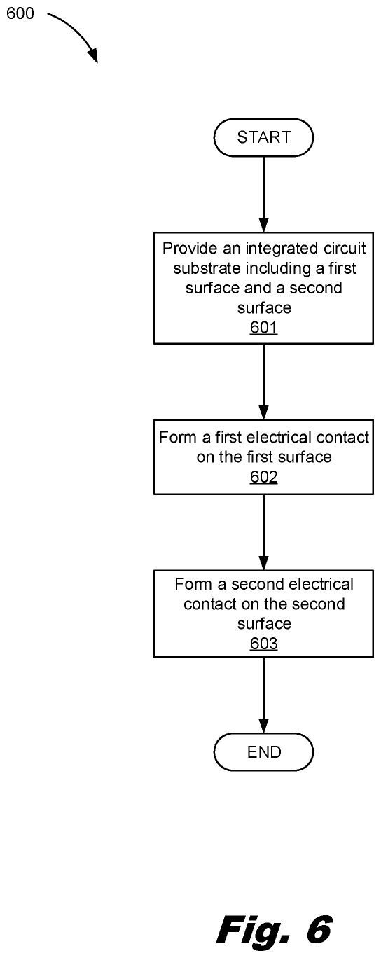

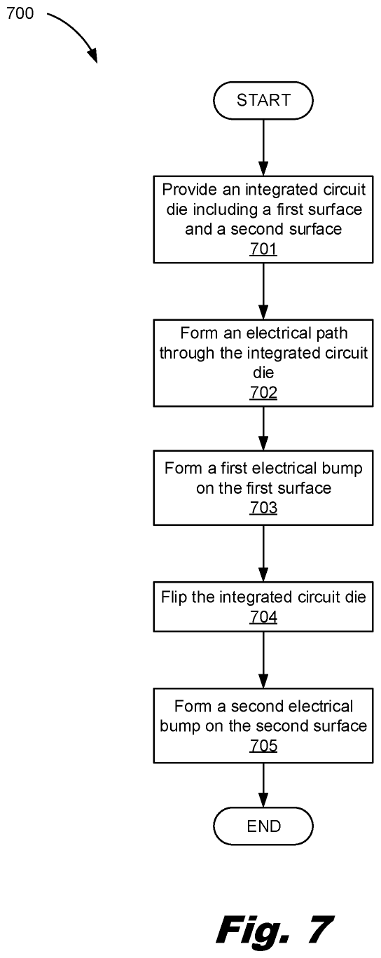

In some examples, these bumps (208) are formed of solder balls. In other examples however, the bumps (208) are formed of a material that does not rely on soldering or that may be non-solderable. That is, in other integrated circuit devices (100), metal bumps may be made for soldering. These bumps may be referred to as “solder balls” because they are formed of solder alloys. However, when connecting to electrical traces in a 3D printed object, a non-soldering electrical connection may be made. Accordingly, the bumps (208) may be formed of a material that may be attached without soldering and that is instead selected for enhanced contact with the conductive agents used in the additive manufacturing process. For example, the bumps (208) may be formed of copper, silver, or other conductive metals for connecting to conductive traces used in additive manufacturing processes. A method for forming the bumps (208) on either surface is presented below in connection with FIGS. 6 and 7.

In some examples, the integrated circuit device (100) includes a passivation layer (212) that protects the circuit layers, i.e., the integrated circuit die (102) and other electronic components, from environmental conditions. Specifically, the passivation layer (212) may prevent air, humidity, and other environmental contaminants from contacting the circuit layer underneath, which if not prevented may lead to corrosion or similar degradation of the surface.

FIG. 2 also depicts through silicon vias (TSVs) (210) which provide electrical connection of opposite sides of the die substrate. That is, a TSV (210) connects a first bump (208-1) on one side of an integrated circuit die (102) to the opposite side. Such a TSV (210) may be formed by creating a small opening in the silicon substrate and depositing a conducting material into the opening so that an electrical contact is achieved through the silicon substrate.

As depicted in FIG. 2, an integrated circuit device (100) may also include an interlayer dielectric (ILD) (211). The ILD (211) is an insulative layer between the metal wires and connections deposited on the surface of an integrated circuit die (102). In some examples, an integrated circuit device (100) includes two or more metal layers with the ILD separating them. However, in the example depicted in FIG. 2, just one ILD (211) layer is depicted on the integrated circuit die (102).

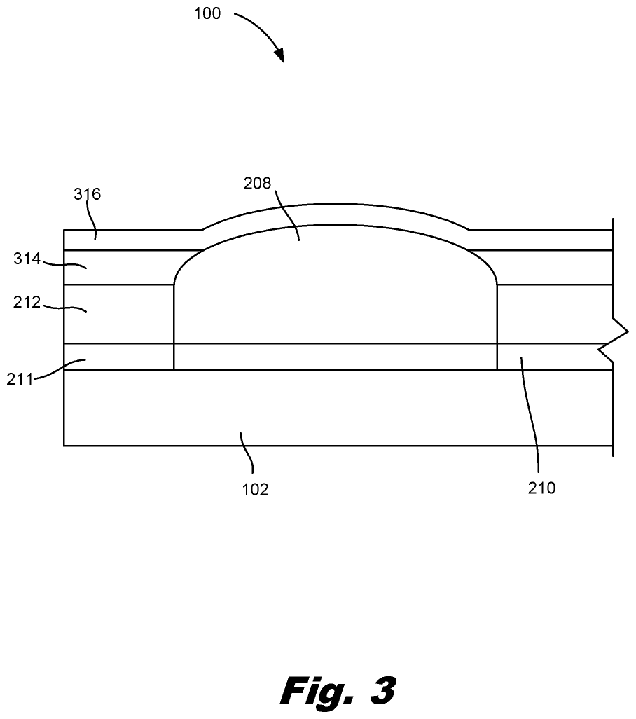

FIG. 3 is a diagram of an integrated circuit device (100) with electrical contacts (FIG. 1, 106) on multiple surfaces (FIG. 1, 104), according to another example of the principles described herein. Specifically, FIG. 3 depicts a single contact bump (208) on a first surface (FIG. 1, 104-1) of the integrated circuit device (100). As described above, when used in an additive manufacturing process, the integrated circuit device (100) may be exposed to conditions that an integrated circuit in another application might not be exposed to.

Specifically, during the additive manufacturing operation, a fusing agent may be applied to a surface of a powdered build material. The fusing agent is activated via application of heat energy to harden portions of the 3D printed object. Accordingly, an integrated circuit device (100) inside a 3D printed object may be exposed to prolonged exposures to high levels of heat energy and environmental contaminants.

Accordingly, in addition to being covered by a first passivation layer (212), which as described above renders the surface of the integrated circuit device (100) inert and protected from air, humidity, or other environmental contaminants, the first surface (FIG. 1, 104-1) and/or the second surface (FIG. 1, 104-2) may be coated with a second passivation layer (314). The second passivation layer (314) relieves thermal stress between the integrated circuit device (100) and a medium used in additive manufacturing. That is, the integrated circuit device (100), when placed in a 3D printed object, may be subject to cycles of thermal expansion and contraction stress between the surface of the integrated circuit device (100) and the polymer used in 3D printing (e.g. polyamide-12) due to the cyclic use of heat energy to fuse powdered build material. In one particular example, this second passivation layer (314) may be formed of any variety of thermoplastic polyurethanes (TPUs) or other elastomers which have high flexural yield and low susceptibility to fatigue, allowing for numerous cycles of strain without crack initiation during temperature changes. As with the first passivation layer (212), openings at the bond pad locations may be etched into the second passivation layer (314) to allow contact and deposition of metal bumps (208).

In some examples, the integrated circuit device (100) may include a dissolving topcoat (316) disposed over at least a first surface (FIG. 1, 104-1) and the second surface (FIG. 1, 104-2). The dissolving topcoat (316) further protects the integrated circuit device (100) and dissolves under the heat applied during an additive manufacturing process.

Specifically, as described above, the bumps (208) may be formed of a conductive material such as copper or silver instead of tin solder. This conductive metal may be more prone to oxidation or corrosion as compared to tin solder. Accordingly, in conjunction with, or instead of, a second passivation layer (314), a dissolving topcoat (316) of inert material may be applied to protect the non-solder metal used to bump the integrated circuit die (102).

This dissolving topcoat (316) may include organic compounds, aqueous components, solvents, or a combination of the above such that the dissolving topcoat (316) may evaporate or sublimate (for example naphthalene, T_{S}80 C) when introduced into an additive manufacturing device. That is, the dissolving topcoat (316) does not evaporate during shipping, when the integrated circuit device (100) is taken out of a package, or when loading a tray of integrated circuit devices (100) into an additive manufacturing device. However, once the additive manufacturing device picks up the integrated circuit device (100) and moves it towards the print bed, the rising temperature will evaporate the dissolving topcoat (316). That is, the dissolving topcoat (316) evaporates as the integrated circuit device (100) is moved into the warm printing environment and not before. As a particular example, the dissolving topcoat (316) may remain intact up to temperatures of 50 degrees Celsius (C) but may begin to dissolve around 80 C.

As such, the metal bump (208) remains protected from oxidation until just before placement of the integrated circuit device (100) into the additive manufacturing bed and/or the deposition of a powder layer and agents. Protection of the non-solderable bumps (208) in this fashion increases the quality of the contact between the bump (208) and any electrical trace formed in the additive manufacturing process.

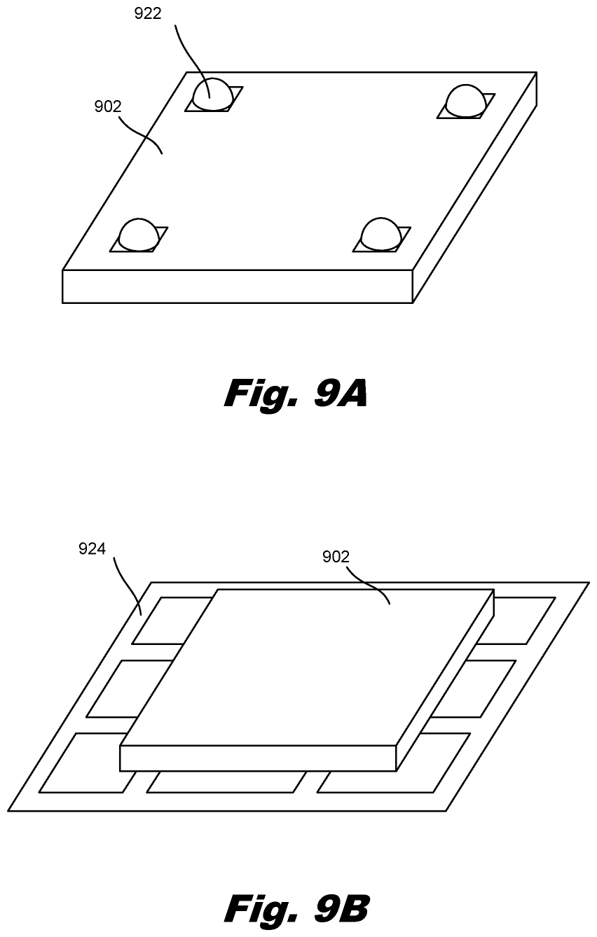

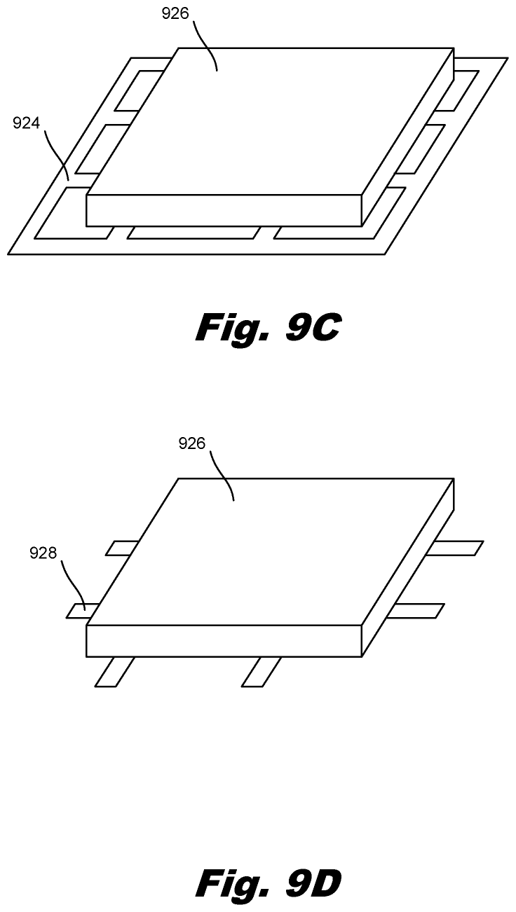

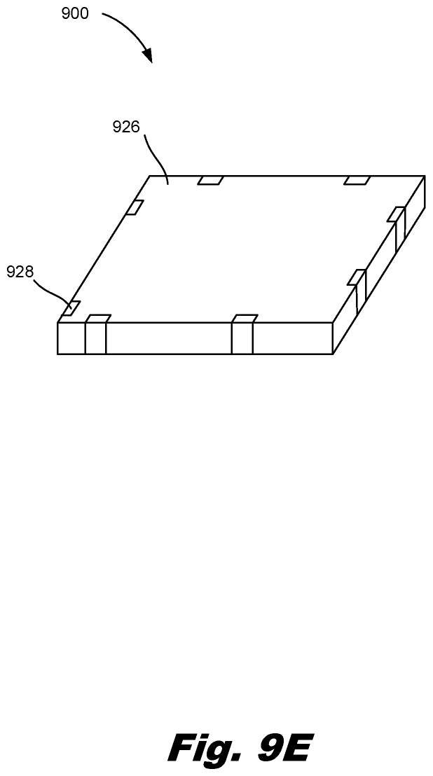

This dissolving topcoat (316) may also be applied to leads that are folded around an encapsulant as depicted in FIGS. 9E-15. FIG. 3 also depicts the TSV (210) and ILD (211) described above.

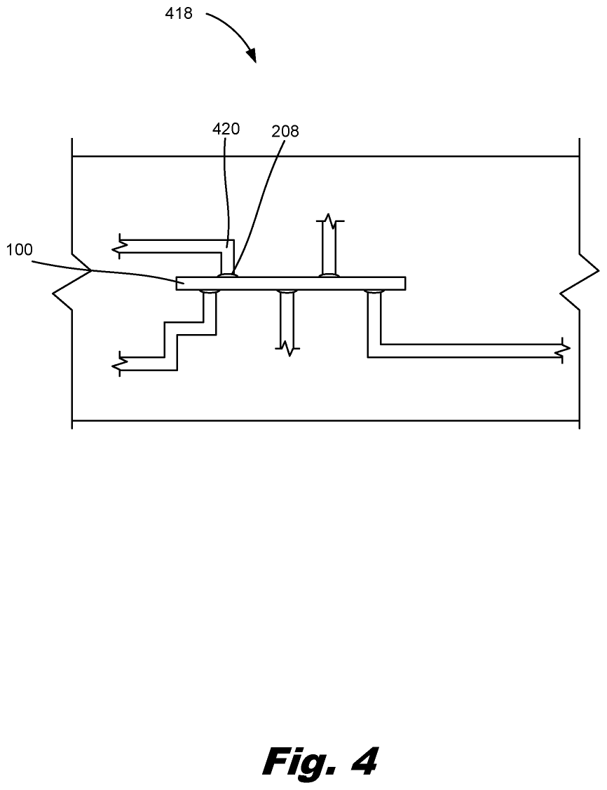

FIG. 4 is a diagram of an integrated circuit (100) with electrical contacts (FIG. 1, 106) on multiple surfaces (FIG. 1, 104) disposed within a three-dimensional (3D) printed object (418), according to an example of the principles described herein. As described above, a 3D printed object (418) may be formed in any variety of additive manufacturing devices implementing any number of additive manufacturing techniques. In one example, to form the 3D printed object (418), a build material, which may be powder, is deposited on a bed. A fusing agent is then dispensed onto portions of the layer of build material that are to be fused to form a layer of the 3D printed object (418). The system that carries out this type of additive manufacturing may be referred to as a powder and fusing agent-based system. The fusing agent disposed in the desired pattern increases the energy absorption of the layer of build material on which the agent is disposed. The build material is then exposed to energy such as electromagnetic radiation. The electromagnetic radiation may include infrared light, laser light, or other suitable electromagnetic radiation. Due to the increased heat absorption properties imparted by the fusing agent, those portions of the build material that have the fusing agent disposed thereon heat to a temperature greater than the fusing temperature for the build material. By comparison, the applied heat is not so great so as to increase the heat of the portions of the build material that are free of the agent to this fusing temperature. This process is repeated in a layer-wise fashion to generate a 3D object (418).

FIG. 4 clearly depicts the integrated circuit device (100) placed in contact with electrical traces (420) formed in the build material of the 3D printed object (418). That is, the integrated circuit device (100) is surrounded by build material and electrical traces (420) are formed to contact the electrical contacts (FIG. 1, 106), which in the example depicted in FIG. 4 are metallic bumps (208) on the surface of the integrated circuit device (100). For simplicity, one example of an electrical trace (420) and bump (208) is indicated with a reference number. While FIG. 4 depicts an example with bumps (208) formed on the top and bottom surfaces, bumps (208) may be formed on all surfaces including the side of the integrated circuit device (100).

The electrical traces (420) may be formed by using a conductive agent such as nanoparticle ink. That is, like the fusing agent, the conductive agent may be dispensed onto portions of the layer of build material that are to be fused to form the electrical traces (420). The application of heat sinters the metal nanoparticles in the conductive agent together to form the electrical traces (420).

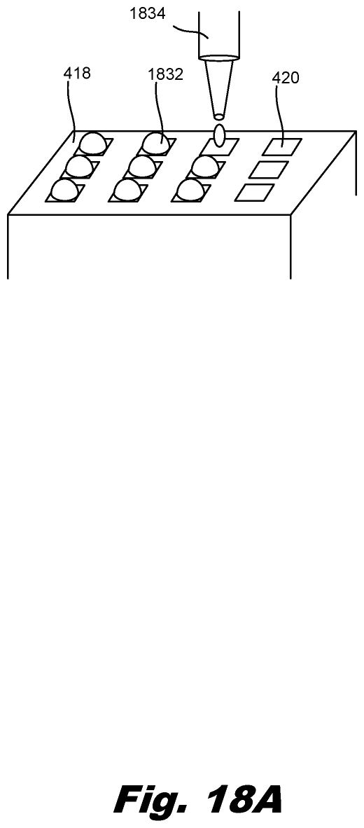

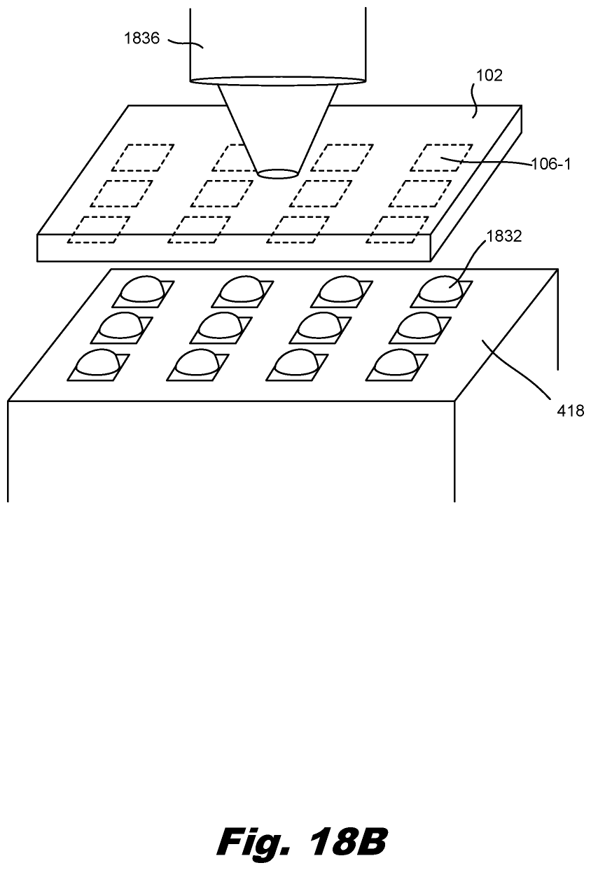

The conductive agent may include conductive nanoparticles in a carrier fluid. Examples of conductive particles that are disposed in the carrier fluid may include silver nanoparticles, copper nanoparticles, gold nanoparticles, nickel nanoparticles, platinum nanoparticles, conductive carbon materials (carbon nanotubes, graphene, graphene oxide, etc.), conductive organic polymers, metal organic salts (copper formate, silver oxalate, etc.), metal organic decomposition inks (these inks take the form MX where M is the metal in a cationic or positive valence state and X is the anion of the salt and may be some carbon containing anion that can decompose at low temperatures and donate its electrons to reduce the metal cation to the metallic state). FIGS. 18A and 18B depict the placement of the integrated circuit device (100) into a 3D printed object (418).

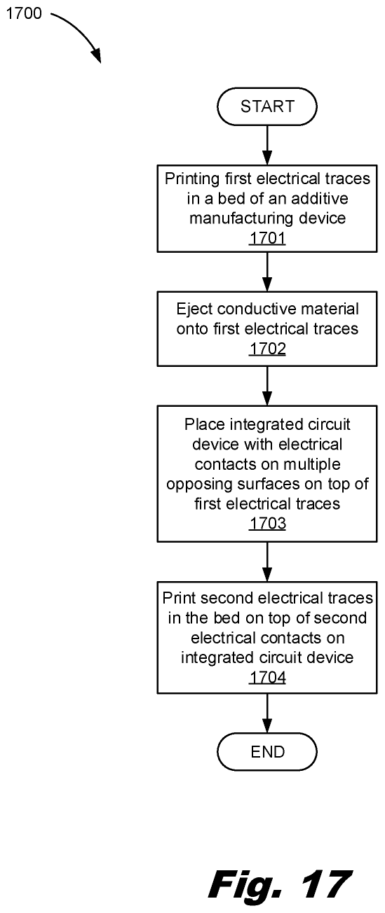

In an example, a conductive material may be formed between the printed electrical traces (420) and the electrical contacts (FIG. 1, 106), e.g., the bumps (208) of the integrated circuit device (100). As described below in connection with FIGS. 17-18B, such a conductive material may increase the electrical conductivity at this connection point.

While particular reference is made to agent-based additive manufacturing processes, the integrated circuit device (100) may be inserted into 3D printed objects (418) formed using other operations. For example, another way to form 3D printed objects (418) is to selectively apply binder to areas of loose build material. In this example, a “latent” part is prepared inside a build bed filled with build material. The build bed may be transferred to a furnace where a first heating operation removes solvents present in the applied binder. As solvents are removed, the remaining binder hardens and glues together build material to convert the “latent” part into a “green” part. The green part is then removed from the bed. In some examples, the green parts are loaded into a sintering furnace where applied heat can cause binder decomposition and causes the build material powder particles to sinter or fuse together into a durable solid form.

In yet another example, a laser, or other power source is selectively aimed at a powder build material, or a layer of a powder build material, to form a slice of a 3D printed object (418). Such a process may be referred to as selective laser sintering.

In yet another example, the additive manufacturing process may use selective laser melting where portions of the powder material, which may be metallic, are selectively melted together to form a slice of a 3D printed object (418).

In one particular example of additive manufacturing referred to as laser fusion, an array of lasers scans each layer of powdered build material to form a slice of a 3D printed object (418). In this example, each laser beam is turned on and off dynamically during the scanning process according to the image slice. Similar to a fusing agent-based system, this laser fusion process is also layer-by-layer.

In yet another example, the additive manufacturing process may involve using a light source to cure a liquid resin into a hard substance. Such an operation may be referred to as stereolithography or photolithography. Accordingly, a device which carries out any of these additive manufacturing processes may be referred to as an additive manufacturing device and in some cases a printer.

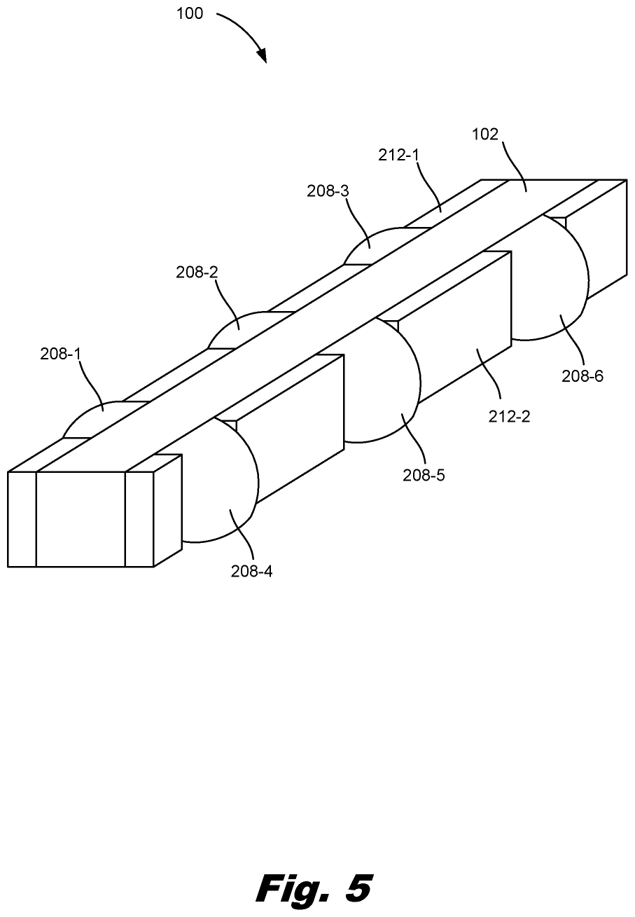

FIG. 5 is a diagram of an integrated circuit device (100) with electrical contacts (FIG. 1, 106) on multiple surfaces (FIG. 1, 104), according to another example of the principles described herein. Specifically, in the example depicted in FIG. 5, rather than placing the integrated circuit device (100) such that the electrical bumps (208-1, 208-2, 208-3, 208-4, 208-5, 208-6) are vertically oriented from one another, the integrated circuit device (100) is positioned such that the electrical bumps (208) are on opposite side surfaces of the integrated circuit device (100).

It may be desirable to form the integrated circuit device (100) to fit within one layer of deposited build material, which may be 100 micrometers thick. In the example depicted in FIG. 2, the reduced height may be achieved in the z-direction by die thinning. In the example depicted in FIG. 5, rather than focus on achieving single-layer thickness in the z-direction relative to the silicon wafer orientation, some integrated circuit substrates (102) are narrow in the x-direction. Accordingly, the desired thinness is achieved in the x-direction rather than the z-direction. Accordingly, using techniques described below in connection with FIG. 7, bumps (208) may be formed on a top and bottom surface, as depicted in FIG. 2. The integrated circuit device (100) may then be rotated 90 degrees as depicted in FIG. 5.

FIG. 6 is a flow chart of a method (600) for forming integrated circuit devices (FIG. 1, 100) with electrical contacts (FIG. 1, 106) on multiple surfaces (FIG. 1, 104), according to an example of the principles described herein.

According to the method (600), an integrated circuit die (FIG. 1, 102) is provided (block 601), which integrated circuit die (FIG. 1, 102) has a first surface (FIG. 1, 104-1) and a second surface (FIG. 1, 104-2). In one particular example, the integrated circuit die (FIG. 1, 102) is a silicon wafer with electronic components such as resistors, transistors, capacitors, and diodes on the surface or disposed within the body of the integrated circuit die (FIG. 1, 102). Such electronic components allow the integrated circuit device (FIG. 1, 100) to carry out the computational operations which many of today's electronic and computing devices rely on.

At least a first electrical contact (FIG. 1, 106-1) is formed (block 602) on the first surface (FIG. 1, 104-1) of the integrated circuit die (FIG. 1, 102) and at least a second electrical contact (FIG. 1, 106-2) is formed (block 603) on the second surface (FIG. 1, 104-2) of the integrated circuit die (FIG. 1, 102).

As described above, the method (600) provides for integrated circuit die (FIG. 1, 102) which themselves include contacts on both sides. Integrated circuit devices (FIG. 1, 100) with electrical contacts (FIG. 1, 106) formed on different surfaces (FIG. 1, 104) increase the range of uses of the integrated circuit devices (FIG. 1, 100) as it allows for electrical connections on any surface exposed to electrical traces (FIG. 4, 420). One example of such an application is within a 3D printed object (FIG. 4, 418). In this example, 3D printed electrical traces (FIG. 4, 420) may be formed and an integrated circuit device (FIG. 1, 100) may be placed such that electrical contacts (FIG. 1, 106) on the bottom surface of the integrated circuit device (FIG. 1, 104) are on top of the traces (FIG. 4, 420). Following placement of the integrated circuit device (FIG. 1, 100), additional traces (FIG. 4, 420) may be printed. These additional traces (FIG. 4, 420) contact the electrical contacts (FIG. 1, 106) that are on the top surface of the integrated circuit device (FIG. 1, 100).

FIG. 7 is a flow chart of a method (700) for forming integrated circuit devices (FIG. 1, 100) with electrical contacts (FIG. 1, 106) on multiple surfaces (FIG. 1, 104), according to another example of the principles described herein. Specifically, FIG. 7 depicts a method (700) for forming an integrated circuit device (FIG. 1, 100) as depicted in FIG. 2 with bumps (FIG. 2, 208) on opposite surfaces of the integrated circuit device (FIG. 1, 100). According to the method (700), an integrated circuit die (FIG. 1, 102) with a first surface (FIG. 1, 104-1) and a second surface (FIG. 1, 104-2) is provided (block 701). This may be performed as described above in connection with FIG. 6.

An electrical path is then formed (block 702) through the integrated circuit die (FIG. 1, 102). In one example, this may include forming a TSV (FIG. 2, 210) through the integrated circuit die (FIG. 1, 102) to create a conductive path through the body of the integrated circuit die (FIG. 1, 102). However, in other examples, the electrical path may be formed (block 702) using other operations.

Once the integrated circuit die (FIG. 1, 102) is fully manufactured and the surface is passivated and etched, a plating such as gold may be applied to form bond pads on the integrated circuit die (FIG. 1, 102). Metal bumps (FIG. 2, 208) may then be formed (block 703) on the first surface (FIG. 1, 104-1). This may include placing a ball of metallic material onto a location where an electrical connection is desired. As described above, in some examples, the bumps (FIG. 2, 208) may be formed of a non-solderable material or a material that does not need to be soldered. However, in other examples the formation (block 703) of the metallic bumps (FIG. 2, 208) may include placing solder balls at locations on the first surface (FIG. 1, 104-1) where electrical connections are desired. This may be done any number of times on the first surface (FIG. 1, 104-1) to form any number of connection points between the first surface (FIG. 1, 104-1) of the integrated circuit device (FIG. 1, 100) and other electrical components.

In some examples, the integrated circuit device (FIG. 1, 100) is thinned. That is, if it is desired that the integrated circuit device (FIG. 1, 100) is to fit within a single printed layer of build material, the side of the integrated circuit die (FIG. 1, 102) without bumps (FIG. 2, 200) formed thereon may be thinned, for example to 100 micrometers thick, 50 micrometers thick, or less.

Whether thinned or not, the integrated circuit die (FIG. 1, 102) may then be flipped (block 704) or inverted. In some examples, flipping (block 704) the integrated circuit die (FIG. 1, 102) may include supporting the integrated circuit die (FIG. 1, 102) prior to flipping. For example, a structural support may be attached to the side of the integrated circuit die (FIG. 1, 102) with bumps (FIG. 2, 208) formed thereon by lightly gluing the structural support to the surface of the bumps (FIG. 2, 208).

The inverted integrated circuit die (FIG. 1, 102) may then be returned to a metal deposition tool for deposition of an additional metal layer on the backside for wiring and bond pads. In some examples, the second passivation layer (FIG. 3, 314) may be applied at this point. The additional metal layer, and potentially the second passivation layer (FIG. 3, 314), may then be etched to expose bond pads on the integrated circuit die (FIG. 1, 102) where the TSVs (FIG. 2, 210), or other electrical path, create a conductive path through the integrated circuit die (FIG. 1, 102). In some examples, the bond pads may be gold plated. Metal bumps (FIG. 2, 208) may then be formed (block 705) on the second surface (FIG. 1, 104-2) as was done on the first surface (FIG. 1, 104-1). The integrated circuit die (FIG. 1, 102) may then be diced, resulting in semiconductor chips with front-side and back-side metal bumps (FIG. 2, 208). In some examples, the dissolving topcoat (FIG. 3, 316) may be applied either before or after the integrated circuit die (FIG. 1, 102) is diced. Accordingly, the present method (700) creates backside bumps (FIG. 2, 208-2) that can be contacted by conductive material in an additive manufacturing process in addition to the topside bumps (FIG. 2, 208-1).

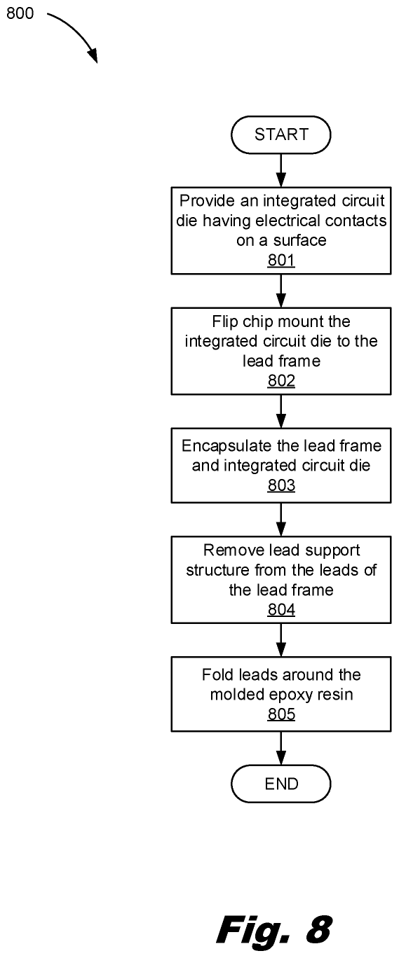

FIG. 8 is a flow chart of a method (800) for forming integrated circuit devices with electrical contacts (FIG. 1, 106) on multiple surfaces, according to another example of the principles described herein. Specifically, FIG. 8 depicts a method (800) for forming an integrated circuit device where the electrical contacts (FIG. 1, 106) are leads that are folded around the surfaces of an encapsulant rather than bumps (FIG. 2, 208) of conductive material on the integrated circuit die (FIG. 1, 102). According to this method (800), electrical contacts are formed on two surfaces of the integrated circuit device and may be formed on additional surfaces. In some examples, a single lead may span multiple surfaces thus providing even greater flexibility to the connectivity of the integrated circuit device.

According to the method (800), an integrated circuit die having electrical contacts (FIG. 1, 106) on a surface is provided (block 801). In some examples, the integrated circuit die that is provided (block 801) is an integrated circuit die of FIG. 1 with electrical contacts (FIG. 1, 106) disposed on both surfaces (FIG. 1, 104). In another example, the integrated circuit die that is provided (block 801) has electrical contacts (FIG. 1, 106) on a single surface (FIG. 1, 104).

The integrated circuit die is then flip chip mounted (block 802) to a lead frame such that the electrical contacts (FIG. 1, 106) align with leads on the lead frame. The lead frame includes a frame with leads extending inward towards the center. The interior portions of the leads are cantilevered and are to make contact with electrical contacts (FIG. 1, 106) on the inverted integrated circuit die. Accordingly, the integrated circuit die is inverted and attached to the lead frame. In one particular example, electrical contacts (FIG. 1, 106) on the integrated circuit die are soldered to the free ends of the lead frame.

In some examples, the method (800) includes attaching a flexible substrate to the lead frame. The flexible substrate routes the connections from the electrical contacts (FIG. 1, 106) of the integrated circuit die to the leads of the lead frame. If the solder balls are arranged along the perimeter of the integrated circuit die and are not in the interior of the integrated circuit die, a flexible substrate may be omitted and the integrated circuit die may be attached directly to a lead frame without any flexible substrate.

In the example where a flexible substrate is present, the flexible substrate is attached to the lead frame, for example via an adhesive. Still in this example, the integrated circuit die is then flip chip mounted to the flexible substrate which is attached to the lead frame. Specifically, electrical contacts (FIG. 1, 106) on the integrated circuit die are soldered to pads on the flexible circuit, and thereby connected to the leads.

In either example, the integrated circuit die/lead frame may be underfilled with epoxy so as to protect the solder connection between the electrical contacts (FIG. 1, 106) and the leads or flexible substrate. The lead frame, and integrated circuit die (FIG. 1, 102), and potentially the flexible substrate, may then be encapsulated (block 803) in an encapsulant such as a molded epoxy resin to protect the integrated circuit device as well as to provide further strength to the solder connection.

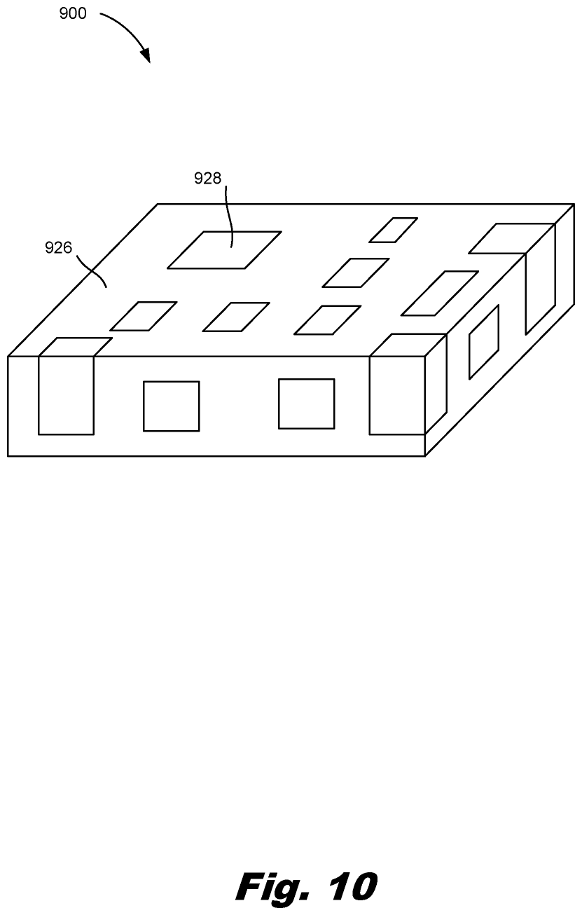

The lead frame supports are then removed (block 804) from the lead frame leads, for example by laser cutting. This integrated circuit die with protruding leads may then be placed into one or a series of lead forming tools to fold (block 805) the leads across the encapsulant to form an integrated circuit device. Specifically, the leads may be folded (block 805) around the corners to a top surface, a bottom surface, or into other 3D configurations for the intended 3D printed application. In some examples, additional cycles of encapsulation and lead forming may be added to create leads inside the perimeter of the integrated circuit device as shown in the example of FIGS. 10, 14, and 15. FIGS. 9A-9E are pictographic illustrations of the method (800).

FIGS. 9A-9E depict the formation of leads on multiple surfaces of an integrated circuit device, according to an example of the principles described herein. Specifically, as depicted in FIG. 9A electrical contacts (FIG. 1, 106) such as solder balls (922) may be placed onto bond pads of the integrated circuit die (902). The placement of these solder balls (922) represent locations where an electrical connection is desired. As described above, the integrated circuit die (902) utilized may be the integrated circuit die (FIG. 1, 102) of FIG. 1 with bumps (FIG. 2, 208) formed on both surfaces of the integrated circuit die (FIG. 1, 102). However, in other examples, the integrated circuit die (902) may be another type, for example with bumps (FIG. 2, 208) or solder balls (922) formed on just one surface.

As depicted in FIG. 9B, the integrated circuit die (902) is inverted and placed over a lead frame (924) with individual leads that are coupled to the frame and that extend inwards. The solder balls (922) are then soldered to the free ends of the leads on the lead frame (924). In some examples, an underfill material is injected to encapsulate and protect the solder connections.

As depicted in FIG. 9C, an encapsulant (926) is then formed over the integrated circuit die (FIG. 9A, 902). At this point, the lead supports may be cut from the frame portion leaving leads (928) that are 1) coupled to the integrated circuit die (FIG. 9A, 902) via the solder balls (922) and 2) that are free to be folded about the different sides of the encapsulant (926). FIG. 9D depicts such an example with the leads (928) extending outward to be folded as desired for the particular application.

At this point the individual leads (928) may be folded onto a desired surface of the encapsulant (926) to form an integrated circuit device (900) with leads (928) on multiple surfaces as depicted in FIG. 9E. The operations depicted in FIGS. 9A-9E reduce the thickness of the integrated circuit device (900) by removing the processes of wire bonding as used in other lead frame packages and flip chip mounting to a PCB substrate.

FIG. 10 is a diagram of an integrated circuit device (900) with electrical contacts (FIG. 1, 106) on multiple surfaces, according to another example of the principles described herein. In the examples depicted in FIGS. 10-15, the electrical contacts (FIG. 1, 106) are leads (928) that have been folded across different surfaces of the encapsulant (926). That is, using the principles described above, leads (928) may be formed on additional surfaces of the integrated circuit device (900). In a particular example, an electrical contact (FIG. 1, 106), i.e., a lead (928) spans across multiple surfaces.

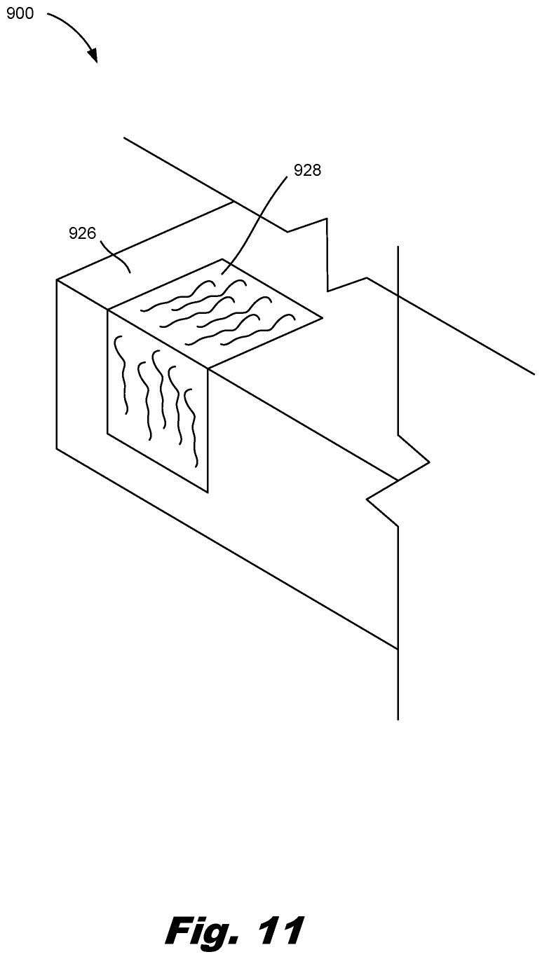

FIG. 11 is a diagram of an integrated circuit device (900) with electrical contacts (FIG. 1, 106) on multiple surfaces, according to another example of the principles described herein. Specifically, FIG. 11 depicts an example where the leads (928) have been roughened, either mechanically or chemically to increase the electrical conductivity at the connection between the leads (928) and the electrical traces (FIG. 4, 420). That is, were the leads (928) to be soldered, it may be desirable for the leads (928) to be smooth and finished. However, in a powder-and-agent conductive trace, a higher quality contact may be achieved with a rough surface. Accordingly, instead of coating the leads (928) with a smooth tin solder, the bare copper or silver may be exposed and the leads (928) may be intentionally roughened, for example with a mechanical scratching or dimpling tool or a chemical etch. Such roughening provides a greater surface area for better conductive agent interaction.

In addition to the leads (928), the surface of the encapsulant (926) may be roughened to ensure the integrated circuit device (900) remains in place during additive manufacturing. That is, it may be that during deposition of a build material or a fusing agent, the integrated circuit device (900) may move within the bed of powder build material. As described above, the build material may be a powder, which may not provide a stable foundation to reduce the movement of the integrated circuit device (900). Accordingly, increasing the coefficient of friction of the integrated circuit device (900) during placement and powder spreading operations may ensure better printing over the integrated circuit device (900). Moreover, alignment of the leads (928) and printed electrical traces (FIG. 4, 420) affects the transmission of electrical signals therebetween. Ensuring firm placement of the integrated circuit device (900) in the bed may also ensure that the leads (928) align with the electrical traces (FIG. 4, 420) that have already been printed (below the integrated circuit device (900)) or that are to be printed on top of the leads (928). Accordingly, the surface of the encapsulant (926) may be scratched or dimples may be formed or molded into the epoxy.

While particular reference is made to roughening the leads (928) of a lead-folded integrated circuit device (900), the electrical bumps (FIG. 2, 208) of the integrated circuit device (FIG. 1, 100) depicted in FIG. 1 may also be roughened.

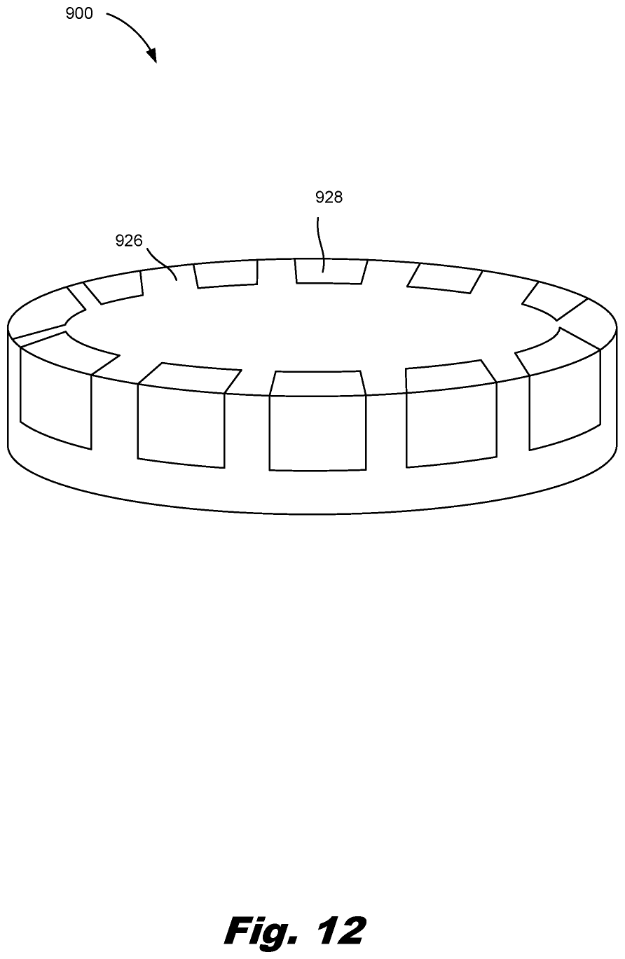

FIG. 12 is a diagram of an integrated circuit device (900) with electrical contacts (FIG. 1, 106) on multiple surfaces, according to another example of the principles described herein. Specifically, in this example, the encapsulant (926) and in some examples the underlying integrated circuit die (FIG. 9, 902) is non-rectangular. That is, using the method (800) described in FIG. 8 and pictographically represented in FIGS. 9A-9E, a radial integrated circuit device (900) may be formed with leads (928) wrapping to one surface or to multiple surfaces. While FIG. 12 depicts a circular non-rectangular integrated circuit device (909), the integrated circuit device (909) may take other non-rectangular forms.

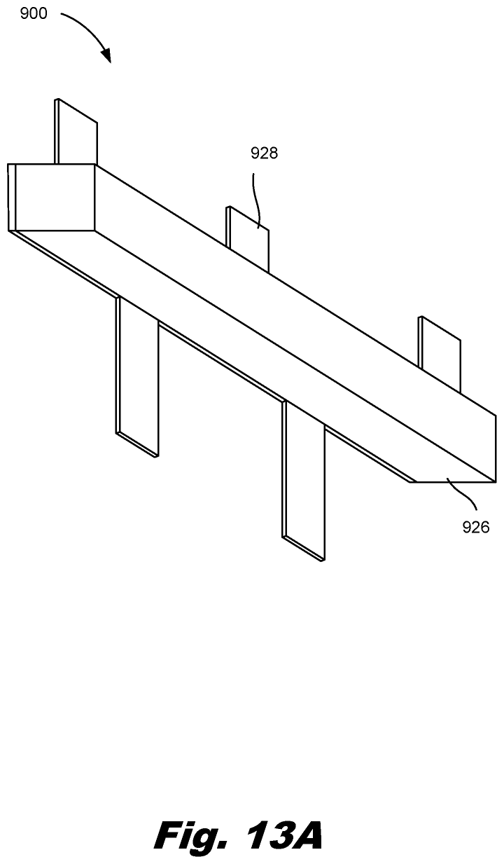

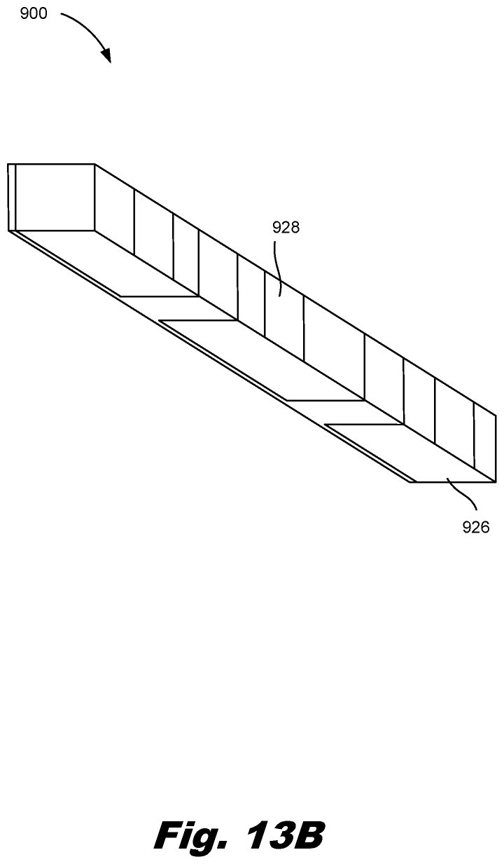

FIGS. 13A and 13B are diagrams of an integrated circuit device (900) with electrical contacts (FIG. 1, 106) on multiple surfaces, according to another example of the principles described herein. In this example, the leads (928) are attached to a thin, linear integrated circuit die (FIG. 9, 902) attached to a lead frame which has been encompassed by the encapsulant (926). In this example, the integrated circuit device (900) is then rotated 90 degrees for placement in the additive manufacturing bed. In one example, the leads (928) may be wrapped completely around the integrated circuit device (900) to enable contact of the conductive agent to the integrated circuit device (900) from any direction.

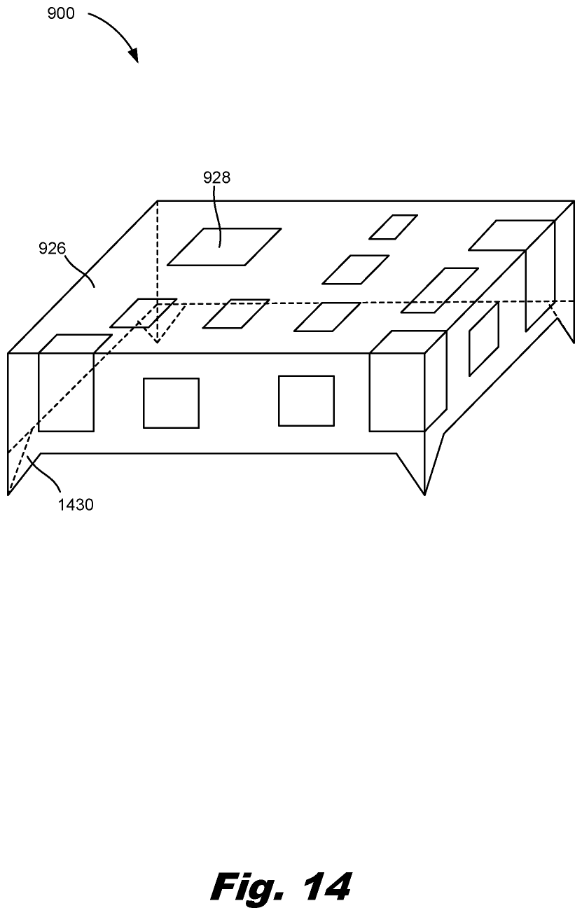

FIG. 14 is a diagram of an integrated circuit device (900) with electrical contacts (FIG. 1, 106) on multiple surfaces, according to another example of the principles described herein. In the example depicted in FIG. 14, the encapsulant (926) is formed to have protrusions (1430) on a surface to retain the integrated circuit device (900) in place during additive manufacturing around the integrated circuit device (900). That is, as described above, during the additive manufacturing process, the integrated circuit device (900) may be acted upon by forces, such as the placement of powdered build material or fusing agent. As another example, during printing the additive manufacturing device may vibrate, which vibrations may cause the integrated circuit device (900) to move across the build material. While a few specific examples have been provided as to how the integrated circuit device (900) may move within the additive manufacturing device, other forces may similarly cause the integrated circuit device (900) to move within the bed. This movement may impact the performance of the integrated circuit device (900) and/or the associated 3D printed object (FIG. 4, 418). Accordingly, the protrusions (1430) maintain the integrated circuit device (900) in place during additive manufacturing.

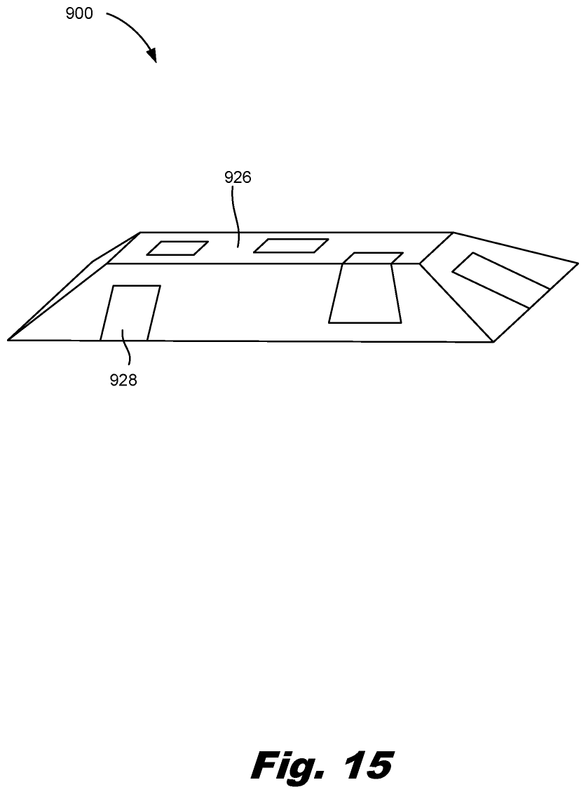

FIG. 15 is a diagram of an integrated circuit device (900) with electrical contacts (FIG. 1, 106) on multiple surfaces, according to another example of the principles described herein. In the example depicted in FIG. 15, a first surface of the encapsulant (926) is narrower than a second surface such that side walls of the integrated circuit device (900) are tapered. As with the protrusions (FIG. 14, 1430), the tapered edge may help set the integrated circuit device (900) in place in the soft powder build material so as to resist being moved by the build material distributor or other processes.

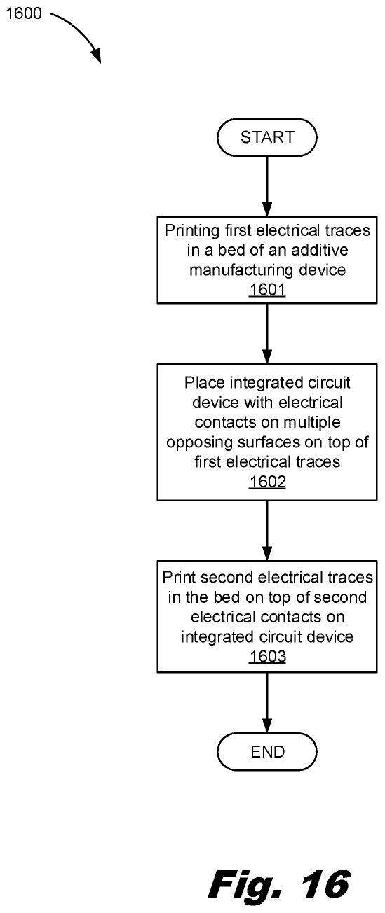

FIG. 16 is a flow chart of a method (1600) for forming integrated circuit devices with electrical contacts (FIG. 1, 106) on multiple surfaces in a 3D printed object (FIG. 4, 418), according to an example of the principles described herein. Note that the method (1600) may place either of 1) an integrated circuit device (FIG. 1, 100) of FIG. 1 with electrical contacts (FIG. 1, 106) on opposite surfaces of the die and 2) an integrated circuit device (FIG. 9, 900) of FIGS. 9A-9E with electrical contacts on multiple surfaces of an encapsulant (FIG. 9, 926) in a 3D printed object (FIG. 4, 418).

According to the method (1600) first electrical traces (FIG. 4, 420) are printed (block 1601) in a bed of an additive manufacturing device. That is, as described above, the additive manufacturing device may lay down a layer of powder build material. Fusing agent may be deposited to form the portions of the build material that are to form the 3D printed object (FIG. 4, 418), and conductive agent may be deposited in areas that are to form the electrical traces (FIG. 4, 420). After application of the fusing and conductive agent, heat may be applied to 1) fuse the areas of the powder build material to form a slice of the 3D object (FIGS. 4, 418) and 2) sinter the metal particles in the conductive agent to form the electrical traces (FIG. 4, 420).

An integrated circuit device is then placed (block 1602) in the additive manufacturing bed. Note that according to the method (1600) either an integrated circuit device (FIG. 1, 100) with electrical contacts (FIG. 1, 106) on both surfaces (FIG. 1, 104) of an integrated circuit die (FIG. 1, 102) or an integrated circuit device (FIG. 9, 900) with leads (FIG. 9, 928) folded around an encapsulant (FIG. 9, 926), may be placed (block 1602) in the additive manufacturing bed.

The integrated circuit device may be placed (block 1602) on top of the first electrical traces (FIG. 4, 420) such that the first electrical contacts, be they bumps (FIG. 2, 208) or leads (FIG. 9, 928) on a bottom surface of the integrated circuit device may be in contact with the printed (block 1601) first electrical traces (FIG. 4, 420).

Second electrical traces (FIG. 4, 420) are then printed (block 1603) in the bed of the additive manufacturing device, again using powder build material and conductive agent. In this example, the second electrical traces (FIG. 4, 420) are printed (block 1603) such that the second electrical traces (FIG. 4, 420) are in contact with the bumps (FIG. 2, 208) or leads (FIG. 9, 928) on the second surface of the integrated circuit device.

FIG. 17 is a flow chart of a method (1700) for forming integrated circuit devices with electrical contacts (FIG. 1, 106) on multiple surfaces, according to another example of the principles described herein.

According to the method (1700) first electrical traces (FIG. 4, 420) are printed (block 1701) in a bed of an additive manufacturing device. This may be performed as described above in connection with FIG. 16. In this example, an electrically conductive material is ejected (block 1702) onto the first electrical traces (FIG. 4, 420). Doing so may provide additional, or ensure a solid, electrical connection between the first electrical leads and the first electrical contacts. The conductive material may be a paste, that has a higher viscosity than the conductive agent that forms the electrical traces (FIG. 4, 420).

With the conductive material positioned, the integrated circuit device may be placed (block 1703) and second electrical traces (FIG. 4, 420) may be printed (block 1704) on top of the electrical contacts on the top of the integrated circuit device. These operations may be performed as described above in connection with FIG. 16.

FIGS. 18A and 18B depict placement of an integrated circuit device with electrical contacts on multiple surfaces into a 3D printed object (418), according to an example of the principles described herein. As described above, either of the integrated circuit devices (FIG. 1, 100, FIG. 9, 900) may be placed in the 3D printed object (FIG. 4, 418). However, FIGS. 18A and 18B depict the placement of an integrated circuit device (FIG. 1, 100) with contacts on opposite surfaces (FIG. 1, 104) of the integrated circuit die (FIG. 1, 102) itself in the 3D printed object (418).

As described above, in order to increase the reliability of bottom-side contacts to the integrated circuit device, an electrically conductive material (1832), such as a solder paste, may be ejected onto each electrical lead (420) as depicted in FIG. 18A. That is, an ejector (1834) may eject an additional single-voxel-sized drop of conductive material (1832) at each voxel where a point of contact is desired. Doing so may result in better contact than depositing the integrated circuit device onto a field or voxel containing the traces (420), particularly an already-fused voxel or set of voxels. As described above, the electrically conductive material (1832) may be different from, and more viscous than, the conductive agent used to form the traces (420). Being more viscous ensures that the conductive material (1832) does not bleed into adjacent areas of build material where an electrical connection is not intended. In one particular example, the viscous conductive material (1832) is a silver paste that has greater conductivity than the conductive agent used to form the electrical trace (420).

As depicted in FIG. 18B, a pick and place tool (1836) may then pick the integrated circuit device (FIG. 1, 102) and place it such that the electrical contacts (106-1) on the bottom surface of the integrated circuit device (100) are positioned over the conductive material (1832) and the corresponding electrical traces (FIG. 4, 420). For simplicity, electrical contacts (FIG. 1, 106-2) on the second surface (FIG. 1, 104-2) of the integrated circuit device (100) are not illustrated.

Such devices and methods 1) allow contact at, and efficient wiring to, multiple surfaces of the integrated circuit device rather than simply one planar surface; 2) enable manufacturing of integrated circuit devices to deliver flexible geometry; 3) enable the construction of devices for single-layer thickness; and 4) are tailored for additive manufacturing operations, including reducing movement after placement and ensuring contact quality in a non-soldered contact. However, it is contemplated that the systems and methods disclosed herein may address other matters and deficiencies in a number of technical areas.

What is claimed is:

1. An integrated circuit device, comprising:
an integrated circuit die comprising a first surface and a second surface;
a first electrical contact disposed on the first surface of the integrated circuit die; and
a second electrical contact disposed on the second surface of the integrated circuit die.

2. The integrated circuit device of claim 1, wherein the electrical contacts are bumps of an electrically conductive material attached without soldering.

3. The integrated circuit device of claim 1, further comprising, disposed over at least one of the first surface and the second surface:
a first passivation layer; and
a second passivation layer to relieve thermal stress between the integrated circuit device and a fusing agent used in additive manufacturing.

4. The integrated circuit device of claim 1, further comprising, disposed over at least one of the first surface and the second surface, a dissolving topcoat which dissolves under heat applied during an additive manufacturing process.

5. The integrated circuit device of claim 1, wherein the integrated circuit device is disposed between printed electrical traces in a three-dimensional printed object.

6. The integrated circuit device of claim 5, further comprising a conductive material formed between the printed electrical traces and electrical contacts of the integrated circuit device.

7. A method, comprising:
providing an integrated circuit die comprising a first surface and a second surface, wherein the second surface is opposite the first surface;
forming a first electrical contact on the first surface of the integrated circuit die; and
forming a second electrical contact disposed on the second surface of the integrated circuit die.

8. The method of claim 7, wherein forming electrical contacts on the first and second surfaces comprises:
forming an electrical path through the integrated circuit die;
forming the first electrical contact on the first surface;
flipping the integrated circuit die; and
forming the second electrical contact on the second surface.

9. The method of claim 7, further comprising roughening a surface of the electrical contacts.

10. A method, comprising:
providing an integrated circuit die having electrical contacts on a surface;
flip chip mounting the integrated circuit die to a lead frame such that the electrical contacts align with leads on the lead frame;
encapsulating the integrated circuit die and the lead frame in an encapsulant,
removing a lead support structure from the leads of the lead frame; and
folding the leads around the encapsulant to form an integrated circuit device.

11. The method of claim 10, further comprising folding a lead around multiple surfaces of the encapsulant.

12. The method of claim 10, further comprising attaching a flexible substrate to the lead frame.

13. The method of claim 10, wherein the integrated circuit device is non-rectangular.

14. The method of claim 10, further comprising forming protrusions on a surface of the encapsulant to retain the integrated circuit device in place during additive manufacturing around the integrated circuit device.

15. The method of claim 10, further comprising tapering side walls of the encapsulant.
